(19) United States
(12) Patent Application Publication
(10) Pub. No.: US 2016/0237571 A1
(43) Pub. Date: Aug. 18, 2016

(54) NOVEL ADHESION PROMOTING AGENTS FOR METALLISATION OF SUBSTRATE SURFACES

(71) Applicant: ATOTECH DEUTSCHLAND GMBH, Berlin (DE)

(72) Inventors: Zhiming LIU, Englewood, CO (US); Hailuo FU, Westminster, CO (US); Sara HUNEGNAW, Denver, CO (US); Lutz BRANDT, Berlin (DE); Tafadzwa MAGAYA, Denver, CO (US)

(73) Assignee: ATOTECH DEUTSCHLAND GMBH, Berlin (DE)

(21) Appl. No.: 15/024,043

(22) PCT Filed: Sep. 22, 2014
(86) PCT No.: PCT/EP2014/070140

§ 371 Date: Mar. 23, 2016

(30) Foreign Application Priority Data
Sep. 26, 2013 (EP) 13186147.8

(51) Int. Cl. C23C 18/18; C23C 18/16; C23C 18/40; C23C 26/00; C23C 28/00; C04B 41/50; C25D 3/12; C25D 3/38; C25D 5/54; C04B 41/52; C04B 41/51; C04B 41/00; C03C 17/36; H01L 21/288

(52) U.S. Cl. CPC C23C 18/1893; C03C 17/3618; C03C 17/3607; C03C 17/3642; C03C 17/3649; C03C 17/3697; C23C 18/1642; C23C 18/1694; C23C 18/405; C23C 18/1882; C23C 18/1653; C23C 26/00; C23C 28/3225; C23C 28/345; H01L 21/2885; C25D 3/12; C25D 3/38; C25D 5/54; C04B 41/52; C04B 41/5111; C04B 41/51; C04B 41/0072; C04B 41/5075; C04B 41/5072; C03C 2217/70; C03C 2218/112; C03C 2218/115; C03C 2218/111

(57) ABSTRACT

A method is provided for metallisation of non-conductive substrates providing a high adhesion of the deposited metal to the substrate material and thereby forming a durable bond. The method applies a novel combination of a metal oxide compound to promote adhesion and a transition metal plating catalyst compound promoting the metal layer formation.

### FIELD OF THE INVENTION

The present invention relates to novel processes for metallisation of non-conductive substrates like glass, ceramic and silicon-based semiconductor type surfaces by applying catalytically active metal oxide compositions. The method results in metal plated surfaces exhibiting high adhesion between the glass or ceramic substrate and the plated metal, while at the same time leaving the smooth substrate surface intact.

The invention can be applied in the area of printed electronic circuits such as fine line circuitry on glass and ceramics for signal distribution (flip chip glass interposers), flat panel display and radio frequency identification (RFID) antennas. Also, it can be applied in metal plating of silicon-based semiconductor substrates.

### BACKGROUND OF THE INVENTION

Various methods to metallise substrates are known in the art.

Conductive substrates can be directly plated with another metal by various wet chemical plating processes, e.g. electroplating or electroless plating. Such methods are well established in the art. Usually, a cleaning pretreatment is applied to the surface before the wet chemical plating process is applied to ensure a reliable plating result.

Various methods are known of coating non-conductive surfaces. In wet chemical methods, the surfaces to be metallised are, after an appropriate preliminary treatment, firstly catalysed and then metallised in an electroless manner and thereafter, if necessary, metallised electrolytically.

Adhesion of the metal layer to the non-conductive substrate is often achieved by mechanical anchoring. However, this requires strong roughening of the substrate surface which negatively impacts the functionality of the metallised surface, e.g. in printed electronic circuits or RFID antennas.

Wet-chemically etching with either HF containing acidic media or hot NaOH, KOH or LiOH containing alkaline media can be employed for both cleaning and roughening of non-conductive substrates, particularly glass or ceramic type substrates. Adhesion is then provided by additional anchoring sites of the roughened surface.

In EP 0 616 053 A1 there is disclosed a method for direct metallisation of non-conductive surfaces, in which the surfaces are firstly treated with a cleaner/conditioner solution, thereafter with an activator solution, for example a colloidal palladium solution, stabilised with tin compounds, and are then treated with a solution which contains compounds of a metal which is more noble than tin, as well as an alkali hydroxide and a complex former. Thereafter, the surfaces can be treated in a solution containing a reducing agent, and can finally be electrolytically metallised.

WO 96/29452 concerns a process for the selective or partial electrolytic metallisation of surfaces of substrates made from electrically non-conducting materials which for the purpose of the coating process are secured to plastic-coated holding elements. The proposed process involves the following steps: a) preliminary treatment of the surfaces with an etching solution containing chromium (VI) oxide; followed immediately by b) treatment of the surfaces with a colloidal acidic solution of palladium-/tin compounds, care being taken to prevent prior contact with adsorption-promoting solutions; c) treatment of the surfaces with a solution containing a soluble metal compound capable of being reduced by tin (II) compounds, an alkali or alkaline earth metal hydroxide, and a complex forming agent for the metal in a quantity sufficient at least to prevent precipitation of metal hydroxides; d) treatment of the surfaces with an electrolytic metallisation solution.

U.S. Pat. No. 3,399,268 reports a method for the electroless deposition of metals on ceramics with catalytic inks comprising a thermosetting resin, a flexible adhesive resin and finely dispersed therein, a metal or metal oxide component. Particularly preferred is cuprous oxide, particularly when it is at least partially reduced with an acid to metallic copper. After deposition of the ink, it can be cured by elevated temperatures. Prior to the electroless deposition of metals the cured ink have to be abraded or mechanically roughened in order to provide a sufficient amount of catalytic sites on its surface. This is an arduous process as it firstly requires dispersing the particles in the ink formulation and secondly requires mechanical roughening of the surface to achieve optimal results.

WO 2003/021004 relates to methods of rendering surfaces catalytic. One example therein concerns the preparation of copper coated glass. A mixture of zirconium alkoxylate and aluminium alkoxylate which additionally contains palladium as catalyst is first deposited on the glass surface and briefly cured to form an organometallic film on the substrate. Thereafter, a copper layer is formed thereon by electroless plating. However, the document fails to teach any further details and applications of thus treated substrates.

U.S. Pat. No. 6,183,828 B1 teaches a method for the manufacturing of rigid memory disks. Within this method a hot substrate is treated with metal alkoxides which decompose upon contact therewith and form the respective oxides. In order to render the surface catalytic for the subsequent nickel plating step a palladium catalyst is deposited thereon.

JP H05-331660 discloses a method for the metallisation of non-conductive substrates such as ceramics and glass. The process comprises the steps of spraying a zinc acetate solution onto the substrate and heating it to form a zinc oxide layer on which palladium as catalyst is deposited prior to copper plating.

U.S. Pat. No. 4,622,069 relates to a method of electroless plating of ceramics whereby a catalyst made of palladium and/or silver organometallic compounds is deposited on the ceramic substrate prior to the metallisation step.

US 2006/0153990 A1 reports UV curable plating catalyst compositions which may be used on non-catalytic substrates such as plastics, glass, ceramics and the like prior to metallisation. These compositions comprise a metal hydroxide or metal hydrous oxide of catalytic active metals (preferably silver), an inert carrier such as silicates, metal oxides, and multi-valent cation and anion pairs, an UV curing agent and a polymer which helps to bind hydrogen from the plating solution.

Sol-gel derived coatings are also reported in the art. Sol-gel is a process which comprises the steps of first hydrolysing suitable metal precursors in a solvent followed by a condensation reaction of the reaction products prior to the application of the thus formed solution on a surface.

U.S. Pat. No. 5,120,339 concerns an alcoholic silica sol-gel application on glass fabrics prior to electroless metal plating and lamination with a thermosetting polymer which may additionally contain a reducible catalyst, e.g. a copper or palladium salt. U.S. Pat. No. 6,344,242 B1 discloses a sol-gel composition comprising a metal alkoxide, an organic solvent, a chloride source and a catalytic metal, preferably palladium which can be used on a substrate prior to metal plating.

Alternatively, conductive polymers can be formed on the non-conductive surface to provide a first conductive layer for subsequent metal plating of the surface.

US 2004/0112755 A1 describes direct electrolytic metallisation of electrically non-conducting substrate surfaces comprising bringing the substrate surfaces into contact with a water-soluble polymer, e.g. a thiophene; treating the substrate surfaces with a permanganate solution; treating the substrate surfaces with an acidic aqueous solution or an acidic microemulsion of an aqueous base containing at least one thiophene compound and at least one alkane sulfonic acid selected from the group comprising methane sulfonic acid, ethane sulfonic acid and ethane disulfonic acid; electrolytically metallizing the substrate surfaces.

U.S. Pat. No. 5,693,209 is directed to a process for directly metallizing a circuit board having non-conductor surfaces, includes reacting the non-conductor surface with an alkaline permanganate solution to form manganese dioxide chemically adsorbed on the non-conductor surface; forming an aqueous solution of a weak acid and of pyrrole or a pyrrole derivative and soluble oligomers thereof; contacting the aqueous solution containing the pyrrole monomer and its oligomers with the non-conductor surface having the manganese dioxide adsorbed chemically thereon to deposit an adherent, electrically conducting, insoluble polymer product on the non-conductor surface; and directly electrodepositing metal on the non-conductor surface having the insoluble adherent polymer product formed thereon. The oligomers are advantageously formed in aqueous solution containing 0.1 to 200 g/l of the pyrrole monomer at a temperature between room temperature and the freezing point of the solution.

Ren-De Sun et al. (Journal of the Electrochemical Society, 1999, 146:2117-2122) teach the deposition of thin ZnO layers on glass by spray pyrolysis, followed by wet chemical Pd activation and electroless deposition of Cu. They reported a moderate adhesion between the deposited copper layer and the glass substrate. The thickness of the deposited copper is about 2 μm.

Depending on the chemical nature of substrate surface, the type of the plated metal and the thickness of the plated metal layer, adhesion of the plated metal layer to said surface can be an issue. For example, adhesion can be too low to provide a reliable bond between the metal layer and the underlying substrate.

### OBJECTIVE OF THE INVENTION

In summary there is a strong industrial drive to ceramic and glass substrates for electronic applications requiring a suitable adhesion promoter to plated Cu which does not alter the substrate properties unfavourably and which is economically feasible.

From an economical perspective, it would be additionally highly desirable to replace the well-established but expensive Pd plating catalyst by cheaper alternatives including reducing the number of required processing steps.

It is therefore the objective of the present invention to provide a method for metallisation of substrates providing a high adhesion of the deposited metal to the substrate material and thereby forming a durable bond. It is a further object of the present invention to provide a method for providing a coating for simultaneous adhesion promotion and catalysis of electroless plating in the metallisation of ceramic and glass substrate surfaces—without substantially adding to or roughening the surface.

Furthermore, it is the object of the present invention to be able to completely or selectively metallise a substrate surface.

### SUMMARY OF THE INVENTION

These objects are solved by a wet chemical method for plating a metal onto a non-conductive substrate comprising the steps of
i. depositing on at least a portion of the non-conductive substrate surface a metal oxide compound selected from the group consisting of zinc oxides, titanium oxides, zirconium oxides, aluminum oxides, silicon oxides, and tin oxides or mixtures of the aforementioned and a transition metal plating catalyst compound selected from the group consisting of copper oxides, nickel oxides, and cobalt oxides and mixtures of the aforementioned, and thereafter
ii. heat treating the non-conductive substrate at a temperature in the range from 350° C. to 1200° C. and thereby forming an adhesive catalytic layer of the metal oxide compound and the transition metal plating catalyst compound on at least a portion of the substrate surface; and thereafter
iii. metal plating at least the substrate surface bearing the transition metal plating catalyst compound by applying a wet-chemical electroless plating method, wherein the composition for plating comprises a source of the metal ions to be plated and a reducing agent.

The method provides metal deposits on the non-conductive substrates exhibiting high adhesion of the deposited metal to the substrate material and thereby forming a durable bond.

It is particularly useful that the process according to the invention does not require any further processing steps such as synthesis of the deposition substances as required by a sol-gel process or mechanical roughening steps.

### DETAILED DESCRIPTION OF THE INVENTION

The present invention provides a metal plating method for metallisation of non-conductive substrates.

Non-conductive substrates suitable to be treated with the plating method according to the present invention comprise glass, ceramic and silicon-based semiconductor materials (also denoted Wafer substrates). Examples for glass substrates comprise silica glass (amorphous silicon dioxide materials), soda-lime glass, float glass, fluoride glass, aluminosilicates, phosphate glass, borate glass, borosilicate glass, chalcogenide glass, aluminium oxide, silicon having an oxidized surface. Substrates of this type are utilized for example as interposers for micro-chip packages and the like. Silicon-based semiconductor materials are used in the Wafer industry.

Ceramic substrates comprise technical ceramics like the oxide based alumina, beryllia, ceria, zirconia oxides or barium based ceramics like BaTiO₃ and non-oxides like carbide, boride, nitride and silicide.

Such non-conductive substrates, particularly glass and Wafer substrates, often have a smooth surface. A “smooth surface” of a non-conductive substrate is defined herein by means of the average surface roughness of the surface Sₐ according to ISO 25178 as determined by optical interference microscopy.

The values for the parameter Sₐ of a “smooth surface” preferably ranges from 0.1 to 200 nm, more preferably from 1 to 100 nm and even more preferably from 5 to 50 nm for glass substrates. For ceramic substrates the surface roughness often is higher. It can be up to an Sₐ value of 1000 nm, e.g. range between 400 to 600 nm.

Substrates having a smooth surface with Sₐ values ranging from 0.1 to 200 nm such as glass and Wafer substrates are preferred, glass is most preferred according to the invention.

The non-conductive substrate is preferably cleaned prior to contacting it with the metal oxide precursor compound. Suitable cleaning methods comprise immersing the substrate in a solution comprising a surface active substance, immersing the substrate in a polar organic solvent or mixture of polar organic solvents, immersing the substrate in an alkaline solution and a combination of two or more of the aforementioned cleaning methods.

Glass substrates for example can be cleaned by immersion into a mixture of 30 wt. % NH₄OH, 30 wt. % H₂O₂, and water for 30 minutes followed by immersion into a mixture of 35 wt. % HCl, 30 wt. % H₂O₂, and water for 30 min. After this substrates are rinsed in DI water and dried.

Metal oxide compounds as defined herein are compounds selected from the group consisting of zinc oxides, titanium oxides, zirconium oxides, aluminum oxides, silicon oxides, and tin oxides or mixtures of the aforementioned. The valency of the metal ions can vary. However, some metals predominantly occur in one valency, e.g. zinc is almost always zinc(II), thus forming Zn(II)O oxide species.

Metal oxide precursor compounds are defined herein as compounds which serve as a source of the corresponding metal oxides. The precursor compounds are capable of forming a thin metal oxide layers on the surface of the non-conductive substrate upon heat treatment. Generally, all metal salts are suitable which form the corresponding metal oxide upon heat treatment. Preferably, heat treatment is under the presence of oxygen. The oxide of the corresponding metal itself generally is not applied directly because it is only poorly soluble in both aqueous as well as organic solvents and therefore difficult to homogeneously apply to the substrate surface.

Most often the corresponding oxides are obtained by heat treatment of the metal oxide precursor compounds. Pyrolysis is a heat treatment process in presence of oxygen. Pyrolysis of the metal oxide precursor compounds results in the formation of the corresponding metal oxide compound.

Typical metal oxide precursor compounds comprise soluble salts of the respective metal. The metal oxide precursor compounds can be organic metal salts and for example be alkoxylates, e.g. methoxylate, ethoxylate, propoxylate and butoxylate, acetates, and acetyl-acetonates. Alternatively, the metal oxide precursor compounds can be inorganic metal salts and for examples be nitrates, halides, particularly chlorides, bromides and iodides.

The metal of the metal oxide precursor is selected from the group consisting of zinc, titanium, zirconium, aluminium, silicon and tin or mixtures of the aforementioned.

The metal oxide formed as mentioned before is selected from the group consisting of ZnO, TiO₂, ZrO₂, Al₂O₃, SiO₂, SnO₂ or mixtures of the aforementioned.

Zinc oxide is the most preferred oxide compound to be applied in a method according to the present invention. Typical zinc oxide precursor compounds are zinc acetate, zinc nitrate, zinc chloride, zinc bromide, and zinc iodide. Another preferred oxide is aluminium oxide. Typical aluminium oxide precursor compounds are acetate, nitrate, chloride, bromide, and iodide of aluminium.

The metal oxide precursor compounds are generally dissolved in a suitable solvent prior to its application to the surface of the non-conductive substrate. This facilitates a homogeneous surface distribution on the substrate surface of the compounds. Suitable solvents comprise polar organic solvents, particularly alcohols like ethanol, propranol, iso-propanol, methoxy-ethanol or butanol.

Additional polar organic solvents comprise alkyl ethers of glycols such as 1-methoxy-2-propanol, monoalkyl ethers of ethylene glycol, diethylene glycol, propylene glycol, ketones such as methyl ethyl ketone, methyl isobutyl ketone, isophorone; esters and ethers such as 2-ethoxyethyl acetate, 2-ethoxyethanol, aromatics such as toluene and xylene, nitrogen containing solvents such as dimethylformamide and N-Methyl pyrrolidone and mixtures of the aforementioned.

Alternatively, the solvents may be water-based solvents. They can also be mixtures of water and organic solvents.

Particularly when using water-based solvents, the solution may further contain one or more wetting agents to improve the wetting of the non-conductive substrate surface. Suitable wetting agents or mixtures thereof include nonionic agents such as nonionic alkylphenol polyethoxy adducts or alkoxylated polyalkylenes and anionic wetting agents such as organic phosphate or phosphonate esters, as well as the diester sulfosuccinates as represented by sodium bistridecyl sulfosuccinate. The amount of the at least one wetting agent ranges from 0.0001 to 5 wt. %, more preferably from 0.0005 to 3 wt. % of the solution.

A solution of the metal acetate in ethanol is a preferred embodiment according to the present invention, with zinc acetate in ethanol being most preferred. A metal oxide precursor compound may comprise a mixture of different salts, but preferably is one salt only.

Alternatively, the metal oxide compound can be directly deposited onto the surface of the non-conductive substrate. Both organic solvents and aqueous media can be used. Generally, the metal oxide compounds are not easily soluble in most common solvents or water and are therefore usually applied to the surface as a colloidal dispersion. Such colloidal dispersions are typically stabilized by surfactants or polymers. It is known to the person skilled in the art on how to prepare such colloidal dispersions.

In methods according to the present invention, deposition of the metal oxide precursor compound is preferred because application of the precursor compounds to the surface can often be better controlled. The precursor compound is then converted to the corresponding metal oxide.

The concentration of the at least one metal oxide compound or metal oxide precursor compound preferably ranges from 0.005 mol/l to 1.5 mol/l, more preferably from 0.01 mol/l to 1.0 mol/l and most preferably from 0.1 mol/l to 0.75 mol/l.

The solution or dispersion containing the metal oxide compound or metal oxide precursor compound according to the present invention can be applied to the non-conductive substrate by methods such as dip-coating, spin-coating, spray-coating, curtain-coating, rolling, printing, screen printing, ink-jet printing and brushing. Such methods are known in the art and can be adapted to the plating method according to the present invention. Such methods result in a uniform film of defined thickness on the surface of the non-conductive substrate.

The thickness of the metal oxide layer is preferably 5 nm to 500 nm, more preferably 10 nm to 300 nm and most preferably 20 nm to 200 nm.

The application can be performed once or several times, e.g. two, three, four, five or up to ten times. The number of application steps varies and depends on the final thickness of the layer of the metal oxide compound desired. Generally, three to five application steps should be sufficient. It is recommended to at least partially dry the coating made of the solution or dispersion prior to application of the next layer. The suitable temperature depends on the solvent used and its boiling point as well as the layer thickness and can be chosen by the person skilled in the art by routine experiments. Generally, a temperature between 150° C. to up to 350° C., preferably between 200° C. and 300° C. should be sufficient. This drying or partial drying of the coating between individual application steps is advantageous as a non-crystalline metal oxide is formed which is stable against dissolution in the solvent of the solution or dispersion containing the metal oxide compound or metal oxide precursor compound and the transition metal plating catalyst precursor compound or the transition metal plating catalyst compound.

The contacting time with the solution or dispersion in step i. is for a time of 10 seconds-20 minutes, preferably between 30 seconds and 5 minutes and even more preferred between 1 minute and 3 minutes. The application temperature depends on the method of application used. For example, for dip, roller or spin coating methods the temperature of application typically ranges between 5° C.-90° C., preferably between 10° C. and 80° C. and even more preferred between 20° C. and 60° C. For spray-pyrolysis method the temperature typically ranges between 200° C.-800° C., preferably between 300° C.-600° C. and most preferably between 350° C.-500° C.

In step ii) heating is performed. This heating can be performed in one or more steps. At a certain stage, it requires a temperature of more than 350° C., preferably more than 400° C. The heating at elevated temperatures results in condensation of the metal oxide to form a mechanically stable metal oxide layer on the substrate surface. Often this metal oxide is in a crystalline state. For ZnO the temperature in this heating step equals or exceeds preferably 400° C.

The heating step ii) is sometimes also referred to as sintering. Sintering is the process of forming a solid, mechanically stable layer of material by heat without melting the material to the point of liquefaction. The heating step ii) is performed at a temperature in the range from 350° C. to 1200° C., more preferably from 350° C. to 800° C. and most preferably from 400° C. to 600° C.

The treatment time preferably is 1 minute to 180 minutes, more preferably 10 minutes to 120 minutes and most preferably 30 minutes to 90 minutes.

In one embodiment of the present invention, it is possible to carry out the heating using a temperature ramp. This temperature ramp may be linear or non-linear. A linear temperature ramp is to be understood in the context of the present invention as a continuous heating starting at lower temperature and rising the temperature steadily until the final temperature is reached. A non-linear temperature ramp according to the present invention may include varying temperature rising speeds (i.e. the change of temperature over time) and may include times without temperature changes and thereby keeping the substrate at the same temperature for a certain period of time. A non-linear temperature ramp may also include linear temperature ramps. Regardless of the type of temperature ramp, it may be followed by a concluding heating step without any temperature change. The substrate may e.g. be kept at 500° C. for 1 h after the temperature ramp.

In one embodiment, a non-linear temperature ramp may include several heating steps as described herein such as the optional drying step and the essential sintering step with temperature rises in between those steps.

If the metal oxide compound is directly deposited onto the surface, the heat treatment predominantly serves to transform the metal oxide layer into a firmly adhesive layer which may additionally be sintered to form a dense layer of the corresponding metal oxide to the non-conductive substrate.

Without being bound by this theory it is believed that upon conversion of the metal oxide precursor compound into the corresponding metal oxide inter-diffusion of the metal oxide into the substrate may occur and metal oxide bridge bonds to the substrate form. Also, partial sintering of the metal oxides is observed. The formed metal oxide (both when applied directly as a metal oxide compound as well as when applied as a metal oxide precursor compound and transformed into the corresponding oxide compound in step ii.) is well adhered to the surface of the non-conductive substrate. For example, if the non-conductive substrate is a glass substrate covalent bonds are formed between the glass substrate and the metal oxide via condensation of the OH-groups.

The surface of the non-conductive substrate is also contacted with a transition metal plating catalyst compound. The transition metal plating catalyst compound is a metal oxide salt wherein the metal is selected from copper, nickel, and cobalt,

Most preferred, the transition metal plating catalyst compound is a copper oxide.

Generally, all metal salts are suitable which form the corresponding metal oxide upon heat treatment: Preferably, heat treatment is carried out in the presence of oxygen.

Most often the corresponding metal oxides of the transition metal plating catalyst compounds are obtained by heat treatment of the transition metal plating catalyst precursor compound. Pyrolysis is the most common and is a heat treatment in the presence of oxygen. Pyrolysis of the transition metal plating catalyst precursor compound results in the respective metal oxide formation.

Typical transition metal plating catalyst precursor compounds comprise soluble salts of the respective metal. The transition metal plating catalyst precursor compounds can be organic metal salts and for example be alkoxylates, e.g. methoxylate, ethoxylate, propoxylate and butoxylate, acetates, and acetyl-acetonates. Alternatively, the transition metal plating catalyst precursor compounds can be inorganic metal salts and for examples be nitrates, halides, particularly chlorides, bromides and iodides.

The metal oxide formed in step ii. preferably is selected from the group consisting of CuO, Cu₂O, NiO, Ni₂O₃, CoO, Co₂O₃, or mixtures of the aforementioned.

In an oxidative environment the higher oxidation state is more likely to be present.

Copper oxide and nickel oxide are the most preferred transition metal plating catalyst compounds to be applied in a method according to the present invention, with a copper oxide being particularly preferred. Typical copper and nickel precursor compounds are the following metal salts: acetate, nitrate, chloride, bromide, iodide.

The transition metal plating catalyst precursor compounds are generally dissolved in a suitable polar solvent prior to its application to the surface of the non-conductive substrate. This facilitates a homogeneous surface distribution on the substrate surface of the compounds. Suitable solvents comprise organic solvents, particularly alcohols like ethanol, propranol, iso-propanol, methoxy-ethanol or butanol.

Additional polar organic solvents comprise alkyl ethers of glycols such as 1-methoxy-2-propanol, monoalkyl ethers of ethylene glycol, diethylene glycol, propylene glycol, ketones such as methyl ethyl ketone, methyl isobutyl ketone, isophorone; esters and ethers such as 2-ethoxyethyl acetate, 2-ethoxyethanol, aromatics such as toluene and xylene, nitrogen containing solvents such as dimethylformamide and N-Methyl pyrrolidone and mixtures of the aforementioned.

Alternatively, the solvents may be water-based solvents, including mixtures of water and organic solvents.

Particularly when using water-based solvents, the solution may further contain one or more wetting agents to improve the wetting of the non-conductive substrate surface. Suitable wetting agents or mixtures thereof include nonionic agents such as nonionic alkylphenol polyethoxy adducts or alkoxylated polyalkylenes and anionic wetting agents such as organic phosphate or phosphonate esters, as well as the diester sulfosuccinates as represented by sodium bistridecyl sulfosuccinate. The amount of the at least one wetting agent ranges from 0.0001 to 5 wt. %, more preferably from 0.0005 to 3 wt. % of the solution.

A solution of the metal acetate in ethanol is a preferred embodiment according to the present invention, with copper and nickel acetate in ethanol being most preferred. A transition metal oxide precursor compound may comprise a mixture of different salts, but preferably is one salt only.

Alternatively, the transition metal plating catalyst compound can be directly deposited onto the surface of the non-conductive substrate. Both organic solvents and aqueous media can be used. Generally, the transition metal plating catalyst compounds are not easily soluble in most common solvents and are therefore usually applied to the surface as a colloidal dispersion. Such colloidal dispersions are typically stabilized by surfactants or polymers. It is known to the person skilled in the art on how to prepare such colloidal dispersions.

In methods according to the present invention, deposition of the transition metal plating catalyst precursor compounds is preferred.

The concentration of at least one transition metal plating catalyst compound or transition metal plating catalyst precursor compound preferably ranges from 0.005 to 1.5 mol/l, more preferably from 0.01 to 1.0 mol/l and most preferably from 0.1 to 0.75 mol/l.

Transition metal plating catalyst compound within the meaning of the present invention means a metal ion containing compound which can be reduced to its metallic form by a reducing agent like formaldehyde, hypophosphite, glyoxalic acid, DMAB (dimethylaminoborane) or NaBH₄. It has been found by the inventors that such metal oxide compounds can be reduced to its metallic form, e.g. with the above mentioned reducing agents. Therefore, metal oxides are preferred as the transition metal plating catalyst compounds in methods according to the present invention.

In Embodiment 2 utilising the transition metal plating catalyst precursor compounds, the method according to the present invention for depositing on at least a portion of the non-conductive substrate surface a metal oxide compound and a transition metal plating catalyst compound comprises:
2. i. contacting the substrate with a metal oxide precursor compound and a transition metal plating catalyst precursor compound, suitable to form the metal oxide compound and the transition metal plating catalyst compound upon heat treatment; and thereafter
2. ii. heat treating the non-conductive substrate as described above and thereby forming an adhesive catalytic layer of the metal oxide compound from the metal oxide precursor compound and the transition metal plating catalyst compound from the transition metal plating catalyst precursor compound on at least a portion of the substrate surface; and thereafter
2. iii. metal plating at least the substrate surface bearing the transition metal plating catalyst compound by applying a wet-chemical electroless plating method, wherein the composition for plating comprises a source of the metal ions to be plated and a reducing agent.

In one embodiment of the present invention, onto the non-conductive substrate the metal oxide compound is deposited as the first layer and thereafter the transition metal plating catalyst compound is deposited as the second layer. In this embodiment, it is important that the transition metal plating catalyst forms the top layer since in the subsequent metal plating step iii. the electroless metal layer is only deposited onto the layer of the transition metal plating catalyst layer.

In Embodiment 3 of the present invention deposition of the metal oxide compound and the transition metal plating catalyst compound is performed as follows:
3. i. depositing on at least a portion of the non-conductive substrate surface a metal oxide compound selected from the group consisting of zinc oxides, titanium oxides, zirconium oxides, aluminum oxides, silicon oxides, and tin oxides or mixtures of the aforementioned, preferably as a dispersion
3. ii. optionally, heat treating the non-conductive substrate as described above and thereby forming an adhesive layer of the metal oxide compound;
3. iii. depositing on at least a portion of the non-conductive substrate surface a transition metal plating catalyst compound selected from the group consisting of copper oxides, nickel oxides, cobalt oxides and mixtures of the aforementioned, and thereafter
3. iv. heat treating the non-conductive substrate as described above and thereby forming an adhesive layer of the metal oxide compound (if step ii. above is omitted) and a catalytic layer of the transition metal plating catalyst compound; and thereafter
3. v. metal plating at least the substrate surface bearing the transition metal plating catalyst compound by applying a wet-chemical electroless plating method, wherein the composition for plating comprises a source of the metal ions to be plated and a reducing agent.

In Embodiment 4 the method according to the present invention comprises depositing on at least a portion of the non-conductive substrate surface a metal oxide compound and a transition metal plating catalyst compound wherein:
4. i. at least a portion of the substrate is contacted with a metal oxide compound selected from the group consisting of zinc oxides, titanium oxides, zirconium oxides, aluminum oxides, silicon oxides, and tin oxides or mixtures of the aforementioned, or metal oxide precursors suitable to form the metal oxide compound upon heat treatment; and thereafter
4. ii. optionally, heat treating the non-conductive substrate as described above and thereby forming an adhesive layer of the metal oxide compound on at least a portion of the substrate surface; and thereafter
4. iii. contacting the substrate with a transition metal plating catalyst compound selected from the group consisting of copper oxides, nickel oxides, and cobalt oxides and mixtures of the aforementioned, or a transition metal plating catalyst precursor compound suitable to form the transition metal plating catalyst compound upon heat treatment; and thereafter
4. v. heat treating the non-conductive substrate as described above and thereby forming an adhesive layer of the metal oxide compound (if step ii. above was omitted) and a catalytic layer of the transition metal plating catalyst compound on at least a portion of the substrate surface; and thereafter
4. vi. metal plating at least the substrate surface bearing the transition metal plating catalyst compound by applying a wet-chemical electroless plating method, wherein the composition for plating comprises a source of the metal ions to be plated and a reducing agent.

The heat treatment as described above can be performed either individually after each contacting steps i. and iii. in Embodiments 3 or 4 or performed after the transition metal plating catalyst compound has been applied to the non-conductive substrate.

In another embodiment of the present invention, the non-conductive substrate is simultaneously contacted with a solution or dispersion containing both the metal oxide compound or the metal oxide compound precursor compound and the transition metal plating catalyst compound or transition metal plating catalyst precursor compound. Thereafter, heat treatment and a conversion to the corresponding metal oxides is performed as described above.

The ratio of the metal oxide compound to the transition metal plating catalyst compound can vary over a wide range and depends on many factors like conductivity, metals used etc. The expert skilled in the art can determine the optimum ratio in routine experiments. Often it is sufficient to have less than 50 wt. % of the transition metal plating catalyst compound in the formed composition. Typical ranges for the ratio of the metal oxide compound to the transition metal plating catalyst compound vary between 5 to 95 wt. % metal oxide compound and the remainder being the transition metal plating catalyst compound, more preferred between 20 to 90 wt. % and even more preferred between 40 and 75 wt. %. A typical mixture of ZnO (metal oxide compound) and CuO (transition metal plating catalyst compound) contains between 5 to 95 wt. % metal oxide compound, the remainder being the transition metal plating catalyst compound, more preferred between 20 to 90 wt. % ZnO and even more preferred between 40 and 75 wt. % ZnO, the rest being CuO.

Optionally, the method can comprise a further step which is performed after method step ii.
iia. contacting the substrate with an aqueous acidic or aqueous alkaline solution.

This additional step increases the average surface roughness (Sₐ) by about 10 nm-50 nm, but does not exceed an increase of 100 nm. The increased roughness is within a range to increase the adhesion of the metal layer to the non-conductive substrate surface without negatively impacting its functionality.

The aqueous acidic solution preferably is an aqueous acidic solution having a pH value of between pH=1-5. Various acids can be used, for example sulfuric acid, hydrochloric acid, or organic acids like acetic acid.

The aqueous alkaline solution alternatively is an aqueous alkaline solution having a pH value of between pH=10-14. Various sources of alkalinity can be used, for example hydroxide salts like sodium, potassium, calcium hydroxide or carbonate salts.

Thereafter, the surface of the non-conductive substrate bearing the catalytic layer is metal plated in step iii. applying a wet-chemical plating method.

Wet-chemical plating methods are well known to the person skilled in the art. Typical wet-chemical plating methods are electrolytic plating applying an external current, immersion plating using the difference in redox potential of the metal to be deposited and the metal on the substrate surface or an electroless plating method using a chemical reducing agent contained in the plating solution.

In a preferred embodiment of the present invention the wet chemical plating method is an electroless plating method, wherein the composition for plating comprises a source of the metal ions to be plated and a reducing agent.

For electroless plating the substrate is contacted with an electroless plating bath containing for example Cu-, Ni-, Co- or Ag-ions. Typical reducing agents comprise formaldehyde, hypophosphite salts like sodium hypophosphite, glyoxylic acid, DMAB (dimethylaminoborane), or NaBH₄.

Such plating solution will react with the transition metal plating catalyst compound on the surface of the non-conductive substrate. If the transition metal plating catalyst compound is a metal oxide contained on the surface of the non-conductive substrate it is reduced by the reducing agent contained in the electroless plating solution. The person skilled in the art will select a suitable agent capable of reducing the transition metal plating catalyst compound in its metal oxide form. By this reduction reaction a first thin layer of metal is formed on the surface of the non-conductive substrate. This layer serves as a so-called nucleation site. Further metal ions from the electroless plating bath are being reduced by the reducing agent contained in the bath and thereby deposited on the nucleation site resulting in a growth of the metal layer in thickness.

By being anchored in the coating itself, these nucleation sites offer strong adhesion to the subsequently plated electroless metal layer.

Preferably, the electroless metal plating solution is a copper, copper alloy, nickel or nickel alloy bath comprising a composition suitable to deposit the corresponding metal or metal alloy.

Most preferably, copper or copper alloys are deposited during the wet chemical deposition, with electroless plating being the most preferred method for wet chemical metal deposition.

Copper electroless plating electrolytes comprise generally a source of copper ions, pH modifiers, complexing agents such as EDTA, alkanol amines or tartrate salts, accelerators, stabilizer additives and a reducing agent. In most cases formaldehyde is used as reducing agent, other common reducing agents are hypophosphite, dimethylaminoborane and borohydride. Typical stabilizer additives for electroless copper plating electrolytes are compounds such as mercaptobenzothiazole, thiourea, various other sulfur compounds, cyanide and/or ferrocyanide and/or cobaltocyanide salts, polyethyleneglycol derivatives, heterocyclic nitrogen compounds, methyl butynol, and propionitrile. In addition, molecular oxygen is often used as a stabilizer additive by passing a steady stream of air through the copper electrolyte (ASM Handbook, Vol. 5: Surface Engineering, pp. 311-312).

Another important example for electroless metal and metal alloy plating electrolytes are compositions for deposition of nickel and alloys thereof. Such electrolytes are usually based on hypophosphite compounds as reducing agent and further contain mixtures of stabilizer additives which are selected from the group comprising compounds of Group VI elements (S, Se, Te), oxo-anions (AsO₂⁻, IO₃⁻, MoO₄²⁻), heavy metal cations (Sn²⁺, Pb²⁺, Hg⁺, Sb³⁺) and unsaturated organic acids (maleic acid, itaconic acid) (Electroless Plating: Fundamentals and Applications, Eds.: G. O. Mallory, J. B. Hajdu, American Electroplaters and Surface Finishers Society, Reprint Edition, pp. 34-36).

In subsequent process steps the electrolessly deposited metal layer can be further structured into circuitry.

In one embodiment of the present invention at least one further metal or metal alloy layer is deposited by electroplating on top of the first metal or metal alloy layer obtained in step iii.

A particularly preferred embodiment to metal plate the substrate applying a wet-chemical plating method comprises:
iiib. contacting the substrate with an electroless metal plating solution; and
iiic. contacting the substrate with an electrolytic metal plating solution.

For electrolytic metallisation, it is possible to use any desired electrolytic metal deposition baths is step iiic., for example for deposition of nickel, copper, silver, gold, tin, zinc, iron, lead or alloys thereof. Such deposition baths are familiar to those skilled in the art.

A Watts nickel bath is typically used as a bright nickel bath, this comprising nickel sulphate, nickel chloride and boric acid, and also saccharine as an additive. An example of a composition used as a bright copper bath is one comprising copper sulphate, sulfuric acid, sodium chloride and organic sulfur compounds in which the sulfur is in a low oxidation state, for example organic sulphides or disulphides, as additives.

The inventors have found that heat treating the deposited metal layers greatly increases the peel strength (PS) of the metal layer to the underlying non-conductive substrate. The extent of the increase was surprising. Such heat treatment is also called annealing. Annealing is a known treatment method to alter the material properties of the metal and for example increases its ductility, relieves internal stress and refines the metal structure by making it homogeneous. It was not apparent that such annealing also results in a greatly increased peel strength between the deposited metal layer and the non-conductive substrate surface.

Such heat treatment is performed in step iv. according to the method of the present invention after the final metal plating step:
iv. heating of the metal plated layer to a temperature of between 150° C. and 500° C.

For this heat treatment the substrate is slowly heated to a maximum temperature of between 150° C. and 500° C., preferably up to a maximum temperature of 400° C. and even more preferred up to a maximum temperature of 350° C. The treatment time varies depending on the substrate material, the plated metal and the thickness of the plated metal layer and can be determined by routine experiments by the person skilled in the art. Generally, the treatment time ranges between 5 minutes and 120 minutes preferably between 10 minutes and 60 minutes and even more preferred a treatment time of up to 20 minutes, 30 minutes or 40 minutes is sufficient.

It is even more advantageous to perform the heat treatment in two, three or even more steps with a sequential increase of hold temperature during the individual steps. Such a stepwise treatment results in particularly high peel strength values between the plated metal layer and the non-conductive substrate.

Typical temperature profiles can be as follows:

a) 100° C.-200° C. for 10 minutes-60 minutes and thereafter 150° C.-400° C. for 10 minutes-120 minutes or
b) 100° C.-150° C. for 10 minutes-60 minutes and optionally thereafter 150° C.-250° C. for 10 minutes-60 minutes and thereafter 230° C.-500° C. for 10 minutes-120 min.

If the method according to the present invention comprises an electroless metal plating step and an electrolytic metal plating step it is recommended to apply a heat treatment step after each metal plating step. The heat treatment after the electroless metal plating step can be performed as described above. Often it is sufficient to perform a one-step heat treatment at a temperature of up to a maximum of between 100° C. and 250° C. for 10 minutes to 120 minutes.

### EXAMPLES

The following experiments are meant to illustrate the benefits of the present invention without limiting its scope. The terms substrates and samples are used interchangeably herein.

General procedure: For adhesive testing purposes the electroless metal layer was further plated electrolytically with 15 μm of copper and thereafter heated at a temperature of 180° C. for 30 min. The plated copper layer was subjected to a 90° angle peel strength testing. The additional copper thickness strongly increased the likelihood of adhesive interfacial failure in case of insufficient adhesion.

In the Examples metal oxide precursors compounds (MO) and plating catalysts (MeO) were employed as listed and identified in Table 1.

### Example 1

### Comparative

The following commercially available three samples were used in this example (all: 1.5×4.0 cm slides):
Borosilicate Glass (Sₐ<10 nm).
Wafer substrate, Si/SiO₂ (Sₐ<10 nm), surface covered with SiO₂ layer having a thickness of about 75 to 85 nm,
Ceramic substrate, Al₂O₃ (Sₐ=450 nm).

The samples are cleaned and treated as described below.

The substrates were contacted with a commercial Pd/Sn catalyst (Adhemax® Activator, Atotech Deutschland GmbH) containing 50 ppm Pd-ions and 2.5 g/L of SnCl₂ for 5 minutes at a temperature of 25° C. followed by DI water rinsing and an acceleration step (Adhemax® Accelerator, Atotech Deutschland GmbH) for increasing the catalytic activity of the Pd catalyst.

After this, the samples were fully immersed into an electroless Cu plating bath containing copper sulfate as the copper ion source and formaldehyde as reducing agent at 37° C. for 4 minutes resulting in a plating thickness of about 0.25 μm of copper metal. Samples were dried at 120° C. for 10 minutes and then heated at a temperature of 180° C. for 30 minutes.

Adhesion of the plated layer was tested by attaching a Scotch adhesive tape (peel strength of about 2 N/cm) to the electroless copper layer. If the adhesive tape could be removed from the copper metal layer without peeling the metal layer off, the adhesion strength of the metal layer exceeded 2 N/cm.

In those cases where the deposited copper metal layer were peeled off with a rapid movement, the adhesive strength of the layer to the underlying substrates was below 2 N/cm. Complete separation of the electroless copper layers from the substrates was observed for all three sample types (see table 1, 6th column).

A second sample was prepared as described above and an additional copper metal layer was deposited by electrolytic (acidic) copper plating.

For this, an acidic copper plating bath (Cupracid, Atotech Deutschland GmbH) was used containing copper sulfate as the copper ion source and sulfuric acid as well as proprietary leveler and brightener compounds. Plating was performed at a current density of 1.5 ASD resulting in a plated copper layer having a thickness of 15 μm. Essentially, no adhesive metal layer on the substrate material was formed which lead to complete delamination of the plated metal layers.

### Example 2

The following commercially available three samples were used (all: 1.5×4.0 cm slides):
Glass (Sₐ<10 nm).
Wafer substrate, Si/SiO₂ (Sₐ<10 nm), surface covered with SiO₂ layer having a thickness of about 75 to 85 nm,
Ceramic substrate, Al₂O₃ (Sₐ=450 nm).

After cleaning, the samples were successively coated with a ZnO and a CuO layer by spray pyrolysis. First, a solution of the metal oxide precursor compound containing 0.05 mol/l Zn(OAc)₂×2H₂O in EtOH was sprayed by a hand held air brush unit onto the substrates which were heated at a temperature of 400° C. (spray pyrolysis). Then, a further spray pyrolysis at a temperature of 400° C. of the transition metal plating catalyst precursor compound solution containing 0.05 mol/l Cu(OAc)₂×H₂O in EtOH.

The substrate was subsequently heated at a temperature of 500° C. for 60 minutes in air. The thickness of the formed ZnO metal oxide layer was about 150 nm, the thickness of the formed CuO layer was about 30 nm.

After sintering, the samples were treated in an electroless Cu plating bath containing copper sulfate as copper ion source and formaldehyde as reducing agent at a temperature of 37° C. for 15 minutes. A copper layer having a thickness of 1 μm was formed selectively on the portions of the non-conductive substrates covered by ZnO and CuO.

The samples were heated (annealed) stepwise at a temperature of 120° C. for 10 minutes and then at temperature of 180° C. for 30 minutes. Adhesion of the plated layer was tested by attaching a PI adhesive tape (peel strength of about 5 N/cm) to the electroless Cu layer and peeling it off with a rapid movement. There was no separation of the electroless copper layer from the coated substrates. The adhesion of the copper layer to the underlying substrates exceeded 5 N/cm in all cases (see table 1, 7^{th} column).

Thereafter, acid copper (Cupracid, Atotech Deutschland GmbH) was plated at a current density of 1.5 ASD to a thickness of 15 μm. The samples were heated (annealed) stepwise first at a temperature of 120° C. for 10 minutes and then, at temperature of 180° C. for 30 minutes.

No copper separation from the substrate (such as blistering) was observed. The peel strength for the glass substrate was 0.7 N/cm, for the Si/SiO₂ substrate was 0.8 N/cm and for the Al₂O₃ was 6.7 N/cm (see table 1, 8^{th} column).

After reflow treatment of all substrates at 260° C., there were no blisters and the initial peel strength values were retained for all substrates. This reflow test was performed to simulate a component attachment heat stress during reflow soldering. The test was passed since no blisters occurred and the initial peel strength was retained (see table 1, 9^{th} column).

### Example 3

The following commercially available three samples were used (all: 1.5×4.0 cm slides):
Glass (Sₐ<10 nm).
Wafer substrate, Si/SiO₂ (Sₐ<10 nm), surface covered with SiO₂ layer having a thickness of about 75 to 85 nm,
Ceramic substrate, Al₂O₃ (Sₐ=450 nm).

After cleaning, the samples were coated with a mixed ZnO/CuO film by spray pyrolysis.

A solution of 0.025 mol/l Zn(OAc)₂×2H₂O (metal oxide precursor compound) and 0.025 mol/l Cu(OAc)₂×H₂O (transition metal plating catalyst precursor compound) in EtOH was sprayed by a hand held air brush unit onto the non-conductive substrates which were heated to a temperature of 400° C.

The substrates were then sintered at a temperature of 500° C. for 60 minutes in air. The thickness of the thus obtained mixed ZnO/CuO metal oxide layer was about 100 nm.

After sintering, the samples were immersed into an electroless Cu plating bath (containing copper sulfate as copper ion source and formaldehyde as reducing agent) at a temperature of 37° C. for 15 minutes. A copper layer having a thickness of 1 μm was formed selectively on the portions of the non-conductive substrates covered by the ZnO/CuO layer.

Samples were heated (annealed) stepwise first to a temperature of 120° C. for 10 minutes and then to a temperature of 180° C. for 30 minutes. Adhesion of the plated layer was tested by attaching a PI adhesive tape (peel strength of about 5 N/cm) to the electroless Cu layer and peeling it off with a rapid movement. There was no delamination of the electroless copper layers from the coated substrates. The adhesion of the copper layers to the underlying substrates exceeded 5 N/cm (see table 1, 7^{th} column).

Thereafter, acid copper (Cupracid, Atotech Deutschland GmbH) was plated at a current density of 1.5 ASD to a thickness of 15 μm. Samples were heated (annealed) stepwise first to a temperature of 120° C. for 10 minutes and then to a temperature of 180° C. for 30 minutes.

No copper separation from the substrate (such as blistering) was observed. The peel strength for the glass substrate was 0.5 N/cm, for the Si/SiO₂ substrate 0.5 N/cm and for the Al₂O₃ 2.0 N/cm (see table 1, 8^{th} column).

After reflow treatment of all substrates at 260° C., there were no blisters and the initial peel strength values were retained. Hence, the test was passed as these requirements were fulfilled (see table 1, 9^{th} column).

TABLE 1
Metallization conditions of various non-conductive substrates tested and adhesion values obtained.

| | | | | | Eless | | | |
|---|---|---|---|---|---|---|---|---|
| | | | | | Cu | Eless | Galvano | Galvano |
| | MeO catalytic/ | | MO | | Scotch | Cu PI | Cu | Cu |
| | adhesive | | thickness | Sₐ | tape test | tape test | 90 deg PS | Blistering |
| Exp. # | treatment type | substrate | (nm) | (nm) | (2N/cm) | (5 N/cm) | (15 um Cu) | (15 um Cu) |
| 1 | None | glass | — | <10 | fail | — | — | — |
| | (comparative) | Si/SiO2 | — | <10 | fail | — | — | — |
| | | Al2O3 | — | 450-480 | fail | — | — | — |
| 2 | 1. ZnO 2. CuO | glass | ~180 | 15 | — | pass | 0.7 N/cm | Pass |
| | (spray pyrolysis) | Si/SiO2 | ~180 | 24 | — | pass | 0.8 N/cm | Pass |
| | | Al2O3 | ~180 | 462 | — | pass | 6.7 N/cm | Pass |
| 3 | ZnO/CuO | glass | ~100 | 6 | — | pass | 0.5 N/cm | Pass |
| | (spra ypyrolysis) | Si/SiO2 | ~100 | 17 | — | pass | 0.5 N/cm | Pass |
| | | Al2O3 | ~100 | 467 | — | pass | 2.0 N/cm | Pass |

Table 1 shows the results obtained in the examples. The MeO catalytic/adhesive type relates to the metal oxide compounds and transition metal plating catalyst compound on the substrate (2^{nd} column). The MO thickness in the 4^{th} column gives the overall thickness of the combined layers listed in the second column. All samples which were metal plated with methods according to the present invention showed good adhesion of the metal layer to the underlying non-conductive or semiconductor substrates without substantially adding to the roughness of the substrates prior to metallization.

The terms “Pass” in table 1, column 7 stands for an adhesion strength equalling or exceeding 5 N/cm. The term “fail” in column 6 is to be understood as an adhesion strength value of less than 2 N/cm.

90 degree peel strength measurements were performed with a digital force gauge and peel strength tester from IMADA. The adhesion values for all samples are depicted in Table 1, 8^{th} column.

Layer thickness of the metal and metal oxide films was determined by step height on an Olympus LEXT 4000 confocal laser microscope. Roughness values were gathered over a surface area of 120 μm by 120 μm.

1. Wet chemical method for plating a metal onto a non-conductive substrate comprising the steps of
i. depositing on at least a portion of the non-conductive substrate surface a metal oxide compound selected from the group consisting of zinc oxides, titanium oxides, zirconium oxides, aluminum oxides, silicon oxides, and tin oxides or mixtures of the aforementioned and a transition metal plating catalyst compound selected from the group consisting of copper oxides, nickel oxides, and cobalt oxides and mixtures of the aforementioned, wherein the non-conductive substrate is a ceramic, semiconductor or glass substrate and thereafter
ii. heat treating the non-conductive substrate at a temperature of more than 400° C. and thereby forming an adhesive catalytic layer of the metal oxide compound and the transition metal plating catalyst compound on at least a portion of the substrate surface; and thereafter;
iii. metal plating at least the substrate surface bearing the transition metal plating catalyst compound by applying a wet-chemical electroless plating method, wherein the composition for plating comprises a source of the metal ions to be plated and a reducing agent, and
iv. heating of the metal plating layer to a temperature of between 150° and 500° C.

2. Method according to claim 1 wherein the metal oxide compound is selected from the group consisting of ZnO, TiO₂, ZrO₂, Al₂O₃, SiO₂, SnO₂ or mixtures of the aforementioned.

3. Method according claim 1 wherein the transition metal plating catalyst compound is selected from the group consisting of CuO, Cu₂O, NiO, Ni₂O₃, CoO, Co₂O₃ or mixtures of the aforementioned.

4. Method according claim 1 wherein the metal oxide compound and the transition metal plating catalyst compound are deposited onto the substrate surface simultaneously.

5. Method according claim 1 wherein the metal oxide compound and the transition metal plating catalyst compound are deposited onto the substrate surface as a colloidal dispersion.

6. (canceled)

7. Method according claim 1 wherein the depositing on at least a portion of the non-conductive substrate surface a metal oxide compound and the transition metal plating catalyst compound comprises:
i. contacting the substrate with a metal oxide precursor compound and a transition metal plating catalyst precursor compound, suitable to form the metal oxide compound and the transition metal plating catalyst compound upon heat treatment and thereafter
ii. heat treating the non-conductive substrate at a temperature in the range from 350° C. to 1200° C. and thereby forming an adhesive catalytic layer of the metal oxide compound from the metal oxide precursor compound and the transition metal plating catalyst compound from the transition the metal plating catalyst precursor compound on at least a portion of the substrate surface.

8. Method according to claim 7 wherein the metal oxide precursor compound and the transition metal plating catalyst precursor compound is selected from the group consisting of metal methoxylate, ethoxylate, propoxylate, butoxylate, acetate, acetyl-acetonates nitrate, chloride, bromide and iodide.

9. Method according claim 1 wherein a further method step is performed after method step ii.
iia. contacting the substrate with an aqueous acidic or aqueous alkaline solution.

10. Method according claim 1 wherein the substrate is a non-conductive or semiconductor substrate and the step
iii. metal plating the substrate applying a wet-chemical plating method;
comprises:
iiib. contacting the substrate with an aqueous electroless metal plating solution which comprises a source of the metal ions to be plated and a reducing agent; and
iiic. contacting the substrate with an electrolytic metal plating solution.

11. Method according claim 1 wherein the electroless metal plating solution is a nickel or copper plating solution.

12. Method according to claim 10 wherein the electrolytic metal plating solution is a nickel or copper plating solution.

13. (canceled)

14. (canceled)
